(19) United States
(12) Patent Application Publication
(10) Pub. No.: US 2026/0103622 A1
(43) Pub. Date: Apr. 16, 2026

(54) COMPOSITIONS FOR INCREASING MATERIAL REMOVAL RATE OF SILICON CARBIDE AND RELATED METHODS

(71) Applicant: ENTEGRIS, INC., Billerica, MA (US)

(72) Inventors: Chenxuan Li, Naperville, IL (US); Stone Ray Fang, Aurora, IL (US); Shengyu Jin, Bolingbrook, IL (US); Helin Huang, Chicago, IL (US)

(21) Appl. No.: 19/351,131

(22) Filed: Oct. 6, 2025

Related U.S. Application Data
(60) Provisional application No. 63/706,586, filed on Oct. 11, 2024.

(51) Int. Cl. C09G 1/02; H01L 21/306; H01L 21/67

(52) U.S. Cl. CPC C09G 1/02; H10P 52/402; H10P 72/0428

(57) ABSTRACT

Compositions for increasing material removal rate during CMP polishing and related methods are provided. The composition comprises an oxidizer. The composition comprises a plurality of particles. The composition comprises 0.01% to 5% by weight of at least one rare earth metal salt compound based on a total weight of the composition. When the composition is applied to a silicon carbide substrate and when the silicon carbide substrate is polished, the at least one rare earth metal salt compound is present in an amount sufficient to result in an increase in a material removal rate relative to a control composition. The control composition does not comprise the at least one rare earth metal salt compound.

### FIELD

The present disclosure relates to compositions for increasing material removal rate of silicon carbide and related methods.

### BACKGROUND

Chemical mechanical polishing is a process of smoothing surfaces using high removal rates.

### SUMMARY

Some embodiments relate to a composition. In some embodiments, the composition comprises an oxidizer. The composition comprises a plurality of particles. In some embodiments, the composition comprises 0.01% to 5% by weight of at least one rare earth metal salt compound based on a total weight of the composition. In some embodiments, when the composition is applied to a silicon carbide substrate and when the silicon carbide substrate is polished, the at least one rare earth metal salt compound is present in an amount sufficient to result in an increase in a material removal rate relative to a control composition. In some embodiments, the control composition does not comprise the at least one rare earth metal salt compound.

Some embodiments relate to a method. In the method comprises dispensing a composition onto a silicon carbide substrate. In some embodiments, the composition comprises an oxidizer. The composition comprises a plurality of particles. In some embodiments, the composition comprises 0.01% to 5% by weight of at least one rare earth metal salt compound based on a total weight of the composition. In some embodiments, the method comprises polishing the silicon carbide substrate, while the composition is located between a polishing pad and the silicon carbide substrate. In some embodiments, the polishing is sufficient to result in an increase in a material removal rate relative to a control composition. In some embodiments, the control composition does not comprise the at least one rare earth metal salt compound.

Some embodiments relate to a system. In some embodiments, the system comprises a silicon carbide substrate. In some embodiments, the system comprises a composition. In some embodiments, the composition comprises an oxidizer. The composition comprises a plurality of particles. In some embodiments, the composition comprises 0.01% to 5% by weight of at least one rare earth metal salt compound based on a total weight of the composition. In some embodiments, the system comprises a chemical mechanical planarization apparatus. In some embodiments, the chemical mechanical planarization apparatus is configured to bring the composition into contact with the silicon carbide substrate and a polishing pad to remove at least a portion of the silicon carbide substrate.

### DRAWINGS

FIG. 1 is a flowchart of a method for increasing material removal rate of silicon carbide, according to some embodiments.

FIG. 2 is a graphical view illustrating the material removal rate using various compositions having different rare earth metals, according to some embodiments.

FIG. 3 is a graphical view illustrating the material removal rate using various concentrations of lanthanum nitrate, according to some embodiments.

FIG. 4 is a graphical view illustrating the material removal rate using zirconia compositions having different concentrations of the different rare earth metal salt compounds and metal salt compounds, according to some embodiments.

FIG. 5 is a graphical view illustrating the material removal rate using alumina compositions having different rare earth metal salt compounds and metal salt compounds, according to some embodiments.

FIG. 6 is a graphical view illustrating the material removal rate using Ceria, according to some embodiments.

FIG. 7 is a graphical view illustrating the material removal rate using Silica compositions having different rare earth metal salt compounds and metal salt compounds, according to some embodiments.

FIG. 8 is a graphical view illustrating permanganate reduction using various compositions having different rare earth metals, according to some embodiments.

FIG. 9 is a graphical view illustrating buffering effect using various compositions having a second metal salt compound, according to some embodiments.

FIG. 10 is a graphical view illustrating the material removal rate using abrasive-free compositions having different rare earth metal salt compounds and metal salt compounds, according to some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

Embodiments provided herein overcome at least challenges associated with an increased material removal rate (MRR) of silicon carbide from the silicon carbide substrate. Increased material removal rate in silicon carbide polishing application may be achieved by at least one rare earth metal salt compounds or at least one rare earth metal salt compound and at least one metal salt compound in a composition.

Some embodiments relate to a composition. The compositions may be useful for increasing a material removal rate for a substrate, such as, for example and without limitation, a silicon carbide substrate, on either a silicon face and/or a carbon face of the silicon carbide substrate, while also enhancing pH buffer capacity and reducing surface defectivity. The compositions provide improved throughput for single wafer polishing, among other applications, without, for example, having to employ a batch polishing process with tens or hundreds of wafers. In some embodiments, the compositions are useful when employed with soft polishing pads. The compositions disclosed herein exhibit enhanced performance with respect to material removal rates, pH buffer capacity, among other things, relative to conventional slurry compositions used for, for example and without limitation, polishing silicon carbide substrates, among other substrates. The compositions further provide tunability with respect to material removal rate, and surface defectivity, among other things.

The composition may comprise an oxidizer.

In some embodiments, the composition comprises 0.01% to 15% by weight of an oxidizer based on a total weight of the composition, or any range or subrange between 0.01% and 15%. For example, in some embodiments, the oxidizer by weight based on a total weight of the composition may be 0.05% to 14%, 0.1% to 13%, 0.5% to 12%, 1% to 11%, 2% to 10%, 3% to 9%, 4% to 8%, or 5% to 7%. In some embodiments, the oxidizer by weight based on a total weight of the composition may be 0.01% to 14%, 0.01% to 13%, 0.01% to 12%, 0.01% to 11%, 0.01% to 10%, 0.01% to 9%, 0.01% to 8%, 0.01% to 7%, 0.01% to 6%, 0.01% to 5%, 0.01% to 4%, 0.01% to 3%, 0.01% to 2%, 0.01% to 1%, 0.01% to 0.09%, 0.01% to 0.08%, 0.01% to 0.07%, 0.01% to 0.06%, 0.01% to 0.05%, 0.01% to 0.04%, 0.01% to 0.03%, or 0.01% to 0.02%. In some embodiments, the oxidizer by weight based on a total weight of the composition may be 0.02% to 15%, 0.03% to 15%, 0.04% to 15%, 0.05% to 15%, 0.06% to 15%, 0.07% to 15%, 0.08% to 15%, 0.09% to 15%, 0.1% to 15%, 0.5% to 15%, 1% to 15%, 2% to 15%, 3% to 15%, 4% to 15%, 5% to 15%, 6% to 15%, 7% to 15%, 8% to 15%, 9% to 15%, 10% to 15%, 11% to 15%, 12% to 15%, 13% to 15%, or 14% to 15%.

In some embodiments, the oxidizer comprises at least one of a potassium permanganate, a sodium permanganate, a lithium permanganate, a barium permanganate, a hydrogen permanganate, a sodium chlorate, an aluminum perchlorate, or any combination thereof. In some embodiments, the oxidizer comprises a potassium permanganate. In some embodiments, the oxidizer comprises a sodium permanganate. In some embodiments, the oxidizer may be a lithium permanganate. In some embodiments, the oxidizer may be a barium permanganate. In some embodiments, the oxidizer may be a hydrogen permanganate. In some embodiments, the oxidizer may be a sodium chlorate. In some embodiments, the oxidizer may be an aluminum perchlorate.

In some embodiments, the oxidizer comprises at least one of a permanganate, a peroxide, or any combination thereof. In some embodiments, the oxidizer comprises a permanganate. In some embodiments, the oxidizer comprises a peroxide. In some embodiments, the oxidizer comprises at least one of hydrogen peroxide (H₂O₂), FeCl₃, FeF₃, Fe(NO₃)₃, Sr(NO₃)₂, CoF₃, MnF₃, oxone (2KHSO₅·KHSO₄·K₂SO₄), periodic acid, iodic acid, vanadium (V) oxide, vanadium (IV,V) oxide, ammonium vanadate, ammonium salts (e.g., ammonium peroxomonosulfate, ammonium chlorite (NH₄ClO₂), ammonium chlorate (NH₄ClO₃), ammonium iodate (NH₄IO₃), ammonium nitrate (NH₄NO₃), ammonium perborate (NH₄BO₃), ammonium perchlorate (NH₄ClO₄), ammonium periodate (NH₄IO₄), ammonium persulfate ((NH₄)₂S₂O₈), ammonium hypochlorite (NH₄ClO)), ammonium tungstate ((NH₄)₁₀H₂(W₂O₇)), sodium polyatomic salts (e.g., sodium persulfate (Na₂S₂O₈), sodium hypochlorite (NaClO), sodium perborate), potassium polyatomic salts (e.g., potassium iodate (KIO₃), potassium permanganate (KMnO₄), potassium persulfate, nitric acid (HNO₃), potassium persulfate (K₂S₂O₈), potassium hypochlorite (KClO)), tetramethylammonium polyatomic salts (e.g., tetramethylammonium chlorite ((N(CH₃)₄)ClO₂), tetramethylammonium chlorate ((N(CH₃)₄)ClO₃), tetramethylammonium iodate ((N(CH₃)₄)IO₃), tetramethylammonium perborate ((N(CH₃)₄)BO₃), tetramethylammonium perchlorate ((N(CH₃)₄)ClO₄), tetramethylammonium periodate ((N(CH₃)₄)IO₄), tetramethylammonium persulfate ((N(CH₃)₄) S₂O₈)), tetrabutylammonium polyatomic salts (e.g., tetrabutylammonium peroxomonosulfate), peroxomonosulfuric acid, ferric nitrate (Fe(NO₃)₃), urea hydrogen peroxide ((CO(NH₂)₂)H₂O₂), peracetic acid (CH₃(CO)OOH), 1,4-benzoquinone, toluquinone, dimethyl-1,4-benzoquinone, chloranil, alloxan, N-methylmorpholine N-oxide, trimethylamine N-oxide, or any combination thereof. In some embodiments, when the oxidizer is a salt, the oxidizer can be hydrated or anhydrous.

In some embodiments, the oxidizer may control the face selectivity of a silicon carbide substrate. In some embodiments, the face selectivity is a silicon face of the silicon carbide substrate. In some embodiments, the face selectivity is a carbon face of the silicon carbide.

The composition may comprise a plurality of particles.

In some embodiments, the composition comprises 0.01% to 2% by weight of a plurality of particles based on a total weight of the composition, or any range or subrange between 0.01% and 2%. For example, in some embodiments, the composition comprises 0.1% to 2%, 0.2% to 2%, 0.3% to 2%, 0.4% to 2%, 0.5% to 2%, 0.6% to 2%, 0.7% to 2%, 0.8% to 2%, 0.9% to 2%, 1% to 2%, 1.1% to 2%, 1.2% to 2%, 1.3% to 2%, 1.4% to 2%, 1.5% to 2%, 1.6% to 2%, 1.7% to 2%, 1.8% to 2%, 1.9% to 2%, 0.01% to 1.9%, 0.01% to 1.8%, 0.01% to 1.7%, 0.01% to 1.6%, 0.01% to 1.5%, 0.01% to 1.4%, 0.01% to 1.3%, 0.01% to 1.2%, 0.01% to 1.1%, 0.01% to 1%, 0.01% to 0.9%, 0.01% to 0.8%, 0.01% to 0.7%, 0.01% to 0.6%, 0.01% to 0.5%, 0.01% to 0.4%, 0.01% to 0.3%, 0.01% to 0.2%, 0.01% to 0.1%, 0.5% to 1.5%, 0.6% to 1.4%, or 0.7% to 1.3% by weight of the plurality of particles based on the total weight of the composition.

In some embodiments, the composition comprises 0.05% to 10% by weight of the plurality of particles based on the total weight of the composition, or any range or subrange between 0.05% and 10%. For example, in some embodiments, the plurality of particles by weight based on a total weight of the composition may be 0.1% to 9%, 0.5% to 8%, 1% to 7%, 2% to 6%, 3% to 5%, or 4% to 5%. In some embodiments, the plurality of particles by weight based on a total weight of the composition may be 0.05% to 9%, 0.05% to 8%, 0.05% to 7%, 0.05% to 6%, 0.05% to 5%, 0.05% to 4%, 0.05% to 3%, 0.05% to 2%, 0.05% to 1%, 0.05% to 0.09%, 0.05% to 0.08%, 0.05% to 0.07%, or 0.05% to 0.06%. In some embodiments, the plurality of particles by weight based on a total weight of the composition may be 0.06% to 10%, 0.07% to 10%, 0.08% to 10%, 0.09% to 10%, 0.1% to 10%, 0.5% to 10%, 1% to 10%, 2% to 10%, 3% to 10%, 4% to 10%, 5% to 10%, 6% to 10%, 7% to 10%, 8% to 10%, or 9% to 10%.

In some embodiments, the plurality of particles comprises at least one of an alumina, a boehmite, a zirconia, a ceria, a silica, an abrasive-free particle, or any combination thereof. In some embodiments, the plurality of particles comprises an alumina. In some embodiments, the plurality of particles comprises a boehmite. In some embodiments, the plurality of particles comprises a zirconia. In some embodiments, the plurality of particles comprises a ceria. In some embodiments, the plurality of particles comprises a silica. In some embodiments, the plurality of particles comprises an abrasive-free particle. In some embodiments, the abrasive-free particles are no particles.

In some embodiments, the plurality of particles has a Mohs hardness of less than 6. For example, in some embodiments, the plurality of particles has a Mohs hardness of 1 to 6, or any range or subrange between 1 and 6. In some embodiments, the plurality of particles has a Mohs hardness ranging from 1 to 5, 1 to 4, 1 to 3, or 1 to 2. In some embodiments, the plurality of particles has a Mohs hardness ranging from 2 to 6, 3 to 6, 4 to 6, or 5 to 6.

The plurality of particles may have a Z-average particle size of 1 nanometer (nm) to 3000 nm, or any range or subrange between 1 nm and 3000 nm. The Z-average particle size may be referred to as the scattered light intensity-weighted harmonic mean particle diameter which yields from the data analysis algorithm known as cumulants method. The Z-average particle size may be determined according to ISO 22412:2017(en), e.g., by use of a Malvern Zetasizer Nano (Malvern Instruments Ltd., Malvern, UK). For example, the plurality of particles may have a Z-average particle size of 10 nm to 2500 nm, 50 nm to 2000 nm, 100 nm to 1500 nm, 150 nm to 1000 nm, 200 nm to 500 nm, 250 nm to 450 nm, or 300 nm to 400 nm. In some embodiments, the 1 nm to 2750 nm, 1 nm to 2500 nm, 1 nm to 2250 nm, 1 nm to 2000 nm, 1 nm to 1750 nm, 1 nm to 1500 nm, 1 nm to 1250 nm, 1 nm to 1000 nm, 1 nm to 900 nm, 1 nm to 800 nm, 1 nm to 700 nm, 1 nm to 600 nm, 1 nm to 500 nm, 1 nm to 400 nm, 1 nm to 300 nm, 1 nm to 200 nm, 1 nm to 100 nm, 1 nm to 50 nm. In some embodiments, the plurality of particles may have a Z-average particle size of 5 nm to 3000 nm, 10 nm to 3000 nm, 25 nm to 3000 nm, 50 nm to 3000 nm, 100 nm to 3000 nm, 200 nm to 3000 nm, 300 nm to 3000 nm, 400 nm to 3000 nm, 500 nm to 3000 nm, 600 nm to 3000 nm, 700 nm to 3000 nm, 800 nm to 3000 nm, 900 nm to 3000 nm, 1000 nm to 3000 nm, 1100 nm to 3000 nm, 1200 nm to 3000 nm, 1300 nm to 3000 nm, 1400 nm to 3000 nm, 1500 nm to 3000 nm, 1600 nm to 3000 nm, 1700 nm to 3000 nm, 1800 nm to 3000 nm, 1900 nm to 3000 nm, 2000 nm to 3000 nm, 2100 nm to 3000 nm, 2200 nm to 3000 nm, 2300 nm to 3000 nm, 2400 nm to 3000 nm, 2500 nm to 3000 nm, 2600 nm to 3000 nm, 2700 nm to 3000 nm, 2800 nm to 3000 nm, or 2900 nm to 3000 nm.

The composition may comprise at least one rare earth metal salt compound.

In some embodiments, the composition comprises 0.01% to 5% by weight of at least one rare earth metal salt compound based on a total weight of the composition, or any range or subrange between 0.01% and 5%. In some embodiments, for example, the composition comprises 0.1% to 4%, 0.5% to 3%, or 1% to 2% by weight of at least one rare earth metal salt compound based on a total weight of the composition. In some embodiments, the composition comprises 0.1% to 5%, 0.5% to 5%, 1% to 5%, 2% to 5%, 3% to 5%, or 4% to 5% by weight of at least one rare earth metal salt compound based on a total weight of the composition. In some embodiments, the composition comprises 0.01% to 4%, 0.01% to 3%, 0.01% to 2%, 0.01% to 1%, 0.01% to 0.5%, or 0.01% to 0.1% by weight of at least one rare earth metal salt compound based on a total weight of the composition.

In some embodiments, the composition comprises 0.01% to 1% by weight of the at least one rare earth metal salt compound based on the total weight of the composition. In some embodiments, for example, the composition comprises 0.1% to 0.9%, 0.2% to 0.8%, 0.3% to 0.7%, or 0.4% to 0.6% by weight of the at least one rare earth metal salt compound based on the total weight of the composition. In some embodiments, the composition comprises 0.1% to 1%, 0.2% to 1%, 0.3% to 1%, 0.4% to 1%, 0.5% to 1%, 0.6% to 1%, 0.7% to 1%, 0.8% to 1%, or 0.9% to 1% by weight of the at least one rare earth metal salt compound based on the total weight of the composition. In some embodiments, for example, the composition comprises 0.01% to 0.9%, 0.01% to 0.8%, 0.01% to 0.7%, 0.01% to 0.6%, 0.01% to 0.5%, 0.01% to 0.4%, 0.01% to 0.3%, 0.01% to 0.2%, or 0.01% to 0.1% by weight of the at least one rare earth metal salt compound based on the total weight of the composition.

In some embodiments, the at least one rare earth metal salt compound comprises at least one of a rare earth metal oxide compound, a rare earth metal nitrate compound, a rare earth metal oxynitrate compound, or any combination thereof. In some embodiments, the at least one rare earth metal salt compound comprises a rare earth metal oxide compound. In some embodiments, the at least one rare earth metal salt compound comprises a rare earth metal nitrate compound. In some embodiments, the at least one rare earth metal salt compound comprises a rare earth metal oxynitrate compound.

In some embodiments, the rare earth metal oxide compound comprises at least one of a lanthanum oxide, an yttrium oxide, a neodymium oxide, a cerium oxide, a scandium oxide, a praseodymium oxide, a promethium oxide, a samarium oxide, a europium oxide, a gadolinium oxide, a terbium oxide, a dysprosium oxide, a holmium oxide, an erbium oxide, a thulium oxide, an ytterbium oxide, a lutetium oxide, or any combination thereof. In some embodiments, the at least one rare earth metal oxide compound comprises lanthanum oxide. In some embodiments, the at least one rare earth metal oxide compound comprises an yttrium oxide. In some embodiments, the at least one rare earth metal oxide compound comprises a neodymium oxide. In some embodiments, the at least one rare earth metal oxide compound comprises a cerium oxide. In some embodiments, the at least one rare earth metal oxide compound comprises a scandium oxide. In some embodiments, the at least one rare earth metal oxide compound comprises a praseodymium oxide. In some embodiments, the at least one rare earth metal oxide compound comprises a samarium oxide. In some embodiments, the at least one rare earth metal oxide compound comprises a europium oxide. In some embodiments, the at least one rare earth metal oxide compound comprises a gadolinium oxide. In some embodiments, the at least one rare earth metal oxide compound comprises a terbium oxide. In some embodiments, the at least one rare earth metal oxide compound comprises a dysprosium oxide. In some embodiments, the at least one rare earth metal oxide compound comprises a holmium oxide. In some embodiments, the at least one rare earth metal oxide compound comprises an erbium oxide. In some embodiments, the at least one rare earth metal oxide compound comprises an ytterbium oxide. In some embodiments, the at least one rare earth metal oxide compound comprises a lutetium oxide.

In some embodiments, the rare earth metal nitrate compound comprises at least one of lanthanum nitrate (La(NO₃)₃), yttrium nitrate (Y(NO₃)₃), neodymium nitrate (Nd(NO₃)₃), cerium nitrate (Ce(NO₃)₃), scandium nitrate (Sc(NO₃)₃), praseodymium nitrate (Pr(NO₃)₃), promethium nitrate (Pm(NO₃)₃), samarium nitrate (Sm(NO₃)₃), europium nitrate (Eu(NO₃)₃), gadolinium nitrate (Gd(NO₃)₃), terbium nitrate (Tb(NO₃)₃), dysprosium nitrate (Dy(NO₃)₃), holmium nitrate (Ho(NO₃)₃), erbium nitrate (Er(NO₃)₃), thulium nitrate (Tm(NO₃)₃), ytterbium nitrate (Yb(NO₃)₃), lutetium nitrate (Lu(NO₃)₃), or any combination thereof. In some embodiments, the rare earth metal nitrate compound comprises lanthanum nitrate. In some embodiments, the rare earth metal nitrate compound comprises yttrium nitrate. In some embodiments, the rare earth metal nitrate compound comprises neodymium nitrate. In some embodiments, the rare earth metal nitrate compound comprises cerium nitrate. In some embodiments, rare earth metal nitrate compound comprises scandium nitrate. In some embodiments, the rare earth metal nitrate compound comprises praseodymium nitrate. In some embodiments, the rare earth metal nitrate compound comprises promethium nitrate. In some embodiments, the rare earth metal nitrate compound comprises samarium nitrate. In some embodiments, rare earth metal nitrate compound comprises europium nitrate. In some embodiments, the rare earth metal nitrate compound comprises gadolinium nitrate. In some embodiments, the rare earth metal nitrate compound comprises terbium nitrate. In some embodiments, the rare earth metal nitrate compound comprises dysprosium nitrate. In some embodiments, the rare earth metal nitrate compound comprises holmium nitrate. In some embodiments, the rare earth metal nitrate compound comprises erbium nitrate. In some embodiments, the rare earth metal nitrate compound comprises thulium nitrate. In some embodiments, the rare earth metal nitrate compound comprises ytterbium nitrate. In some embodiments, the rare earth metal nitrate compound comprises lutetium nitrate.

In some embodiments, the rare earth metal oxynitrate compound comprises a lanthanum oxynitrate.

In some embodiments, when the composition is applied to a silicon carbide substrate and when the silicon carbide substrate is polished, the at least one rare earth metal salt compound is present in an amount sufficient to result in an increase in a material removal rate relative to a control composition.

In some embodiments, the composition increases the material removal rate relative to a control composition 10% to 99%, or any range or subrange between 10% and 99.9%. In some embodiments, for example, the composition increases the material removal rate relative to a control composition 15% to 95%, 20% to 90%, 25% to 85%, 30% to 80%, 35% to 75%, 40% to 70%, 45% to 65%, or 50% to 60%. In some embodiments, the composition increases the material removal rate relative to a control composition 15% to 99.9%, 20% to 99.9%, 25% to 99.9%, 30% to 99.9%, 35% to 99.9%, 40% to 99.9%, 45% to 99.9%, 50% to 99.9%, 55% to 99.9%, 60% to 99.9%, 65% to 99.9%, 70% to 99.9%, 75% to 99.9%, 80% to 99.9%, 85% to 99.9%, 90% to 99.9%, or 95% to 99.9%. In some embodiments, the composition increases the material removal rate relative to a control composition 10% to 95%, 10% to 90%, 10% to 85%, 10% to 80%, 10% to 75%, 10% to 70%, 10% to 65%, 10% to 60%, 10% to 55%, 10% to 50%, 10% to 45%, 10% to 40%, 10% to 35%, 10% to 30%, 10% to 25%, 10% to 20%, or 10% to 15%.

In some embodiments, the control composition does not comprise the at least one rare earth metal salt compound.

In some embodiments, the composition further comprises 0.01% to 5% by weight of at least one metal salt compound based on the total weight of the composition, or any range or subrange between 0.01% and 5%. In some embodiments, for example, the composition further comprises 0.1% to 4%, 0.5% to 3%, or 1% to 2% by weight of at least one metal salt compound based on the total weight of the composition. In some embodiments, for example, the composition further comprises 0.01% to 4%, 0.01% to 3%, 0.01% to 2%, 0.01% to 1%, 0.01% to 0.5%, or 0.01% to 0.1% by weight of at least one metal salt compound based on the total weight of the composition. In some embodiments, for example, the composition further comprises 0.1% to 5%, 0.5% to 5%, 1% to 5%, 2% to 5%, 3% to 5%, or 4% to 5% by weight of at least one metal salt compound based on the total weight of the composition.

In some embodiments, the at least one metal salt compound comprises an aluminum nitrate (Al(NO₃)₃), an iron (III) nitrate (Fe(NO₃)₃), a strontium nitrate (Sr(NO₃)₂), a gallium nitrate (Ga(NO₃)₃), an indium nitrate (In(NO₃)₃), a silver nitrate (AgNO₃), a zinc nitrate (Zn(NO₃)₂), a zirconium oxynitrate (ZrO(NO₃)₂), a chromium nitrate (Cr(NO₃)₃), or any combination thereof. In some embodiments, the at least one metal salt compound comprises an aluminum nitrate. In some embodiments, the at least one metal salt compound comprises an iron (III) nitrate. In some embodiments, the at least one metal salt compound comprises a strontium nitrate. In some embodiments, the at least one metal salt compound comprises a gallium nitrate. In some embodiments, the at least one metal salt compound comprises an indium nitrate. In some embodiments, the at least one metal salt compound comprises a silver nitrate. In some embodiments, the at least one metal salt compound comprises a zinc nitrate. In some embodiments, the at least one metal salt compound comprises a zirconium oxynitrate. In some embodiments, the at least one metal salt compound comprises a chromium nitrate.

In some embodiments, the composition further comprising 0.01% to 5% by weight of at least one metal salt compound based on the total weight of the composition may provide a buffering effect to the composition to reduce pH drift. In some embodiments, the composition further comprising 0.01% to 5% by weight of at least one metal salt compound based on the total weight of the composition may improve the pH buffer capacity.

In some embodiments, the composition further comprises a pH adjuster. The pH adjuster may be capable of adjusting the pH of the composition. The pH of the compositions may be adjusted using any suitable compound capable of adjusting the pH of the composition. The pH adjuster may be water-soluble and compatible with the other components of the composition. In some embodiments, the pH adjuster comprises at least one of an inorganic acid, a metal salt, an organic acid, an organic hydroxide, or any combination thereof. In some embodiments, the metal salt comprises at least one of a metal nitrate, a metal hydroxide, or any combination thereof. In some embodiments, the pH adjuster comprises at least one of H₂SO₄, HNO₃, HF, H₃PO₄, HCl, Al(NO₃)₃, Mn(NO₃)₂, Zr(NO₃)₂, Fe(NO₃)₃, KOH, NaOH, Al(OH)₃, CH₃SO₃H, polystyrene sulfonic acid (PSSA), toluenesulfonic acid, salicylic acid, oxalic acid, succinic acid, citric acid, malic acid, lactic acid, fumaric acid, NH₄OH, choline hydroxide, or any combination thereof.

In some embodiments, the composition has a pH 1 to 10, when measured at 25° C. and 1 atm, or any range or subrange between 1 and 10. In some embodiments, for example, the composition has a pH of 2 to 9, 3 to 8, 4 to 7, or 5 to 6. In some embodiments, the composition has a pH of 1 to 9, 1 to 8, 1 to 7, 1 to 6, 1 to 5, 1 to 4, 1 to 3, or 1 to 2. In some embodiments, the composition has a pH of 2 to 10, 3 to 10, 4 to 10, 5 to 10, 6 to 10, 7 to 10, 8 to 10, or 9 to 10.

In some embodiments, the composition does not comprise at least aluminum nitrate, zirconium oxynitrate, or any combination thereof.

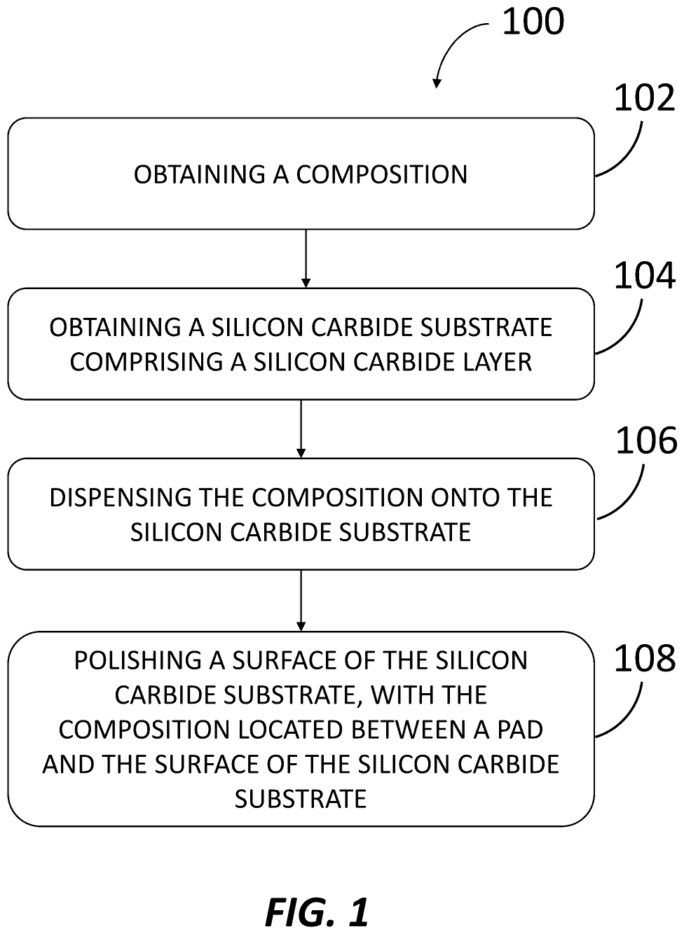

FIG. 1 is a flow diagram of a method for polishing a silicon carbide substrate, according to some embodiments. As shown in FIG. 1, in some embodiments, the method for polishing a silicon carbide substrate comprises one or more of the following steps: dispensing 102 a composition onto a silicon carbide substrate; and polishing 104 the silicon carbide substrate, while the composition is located between a polishing pad and the silicon carbide substrate.

At step 102, in some embodiments, the method comprises dispensing a composition onto a silicon carbide substrate. In some embodiments, the dispensing comprises applying the composition onto the silicon carbide substrate. In some embodiments, the dispensing comprises flowing the composition on the silicon carbide substrate.

In some embodiments, the composition comprises an oxidizer, a plurality of particles, and a 0.01% to 5% by weight of at least one rare earth metal salt compound based on a total weight of the composition. It will be appreciated that the composition may comprise any one or more of the compositions disclosed herein, without departing from the scope of this disclosure.

In some embodiments, the composition comprises an oxidizer. In some embodiments, the oxidizer comprises at least one of a potassium permanganate, a sodium permanganate, a lithium permanganate, a barium permanganate, a hydrogen permanganate, a sodium chlorate, an aluminum perchlorate, or any combination thereof.

In some embodiments, the composition comprises a plurality of particles. In some embodiments, the plurality of particles comprises at least one of an alumina, a boehmite, a zirconia, or any combination thereof.

In some embodiments, the composition comprises 0.01% to 5% by weight of at least one rare earth metal salt compound based on a total weight of the composition. In some embodiments, the at least one rare earth metal salt compound comprises at least one of a rare earth metal oxide compound, a rare earth metal nitrate compound, a rare earth metal oxynitrate compound, or any combination thereof.

In some embodiments, the composition further comprises 0.01% to 5% by weight of at least one metal salt compound based on the total weight of the composition.

In some embodiments, the composition has a pH 1 to 10, when measured at 25° C. and 1 atm.

The silicon carbide on the surface of the silicon carbide substrate may be a polycrystalline hard material. The surface of the silicon carbide substrate may be of any crystalline orientation. In some embodiments, the crystalline orientation of the surface of the silicon carbide substrate may be a silicon face (Si-face), a carbon face (C-face), a mixed face, an m-face, an a-face, any miscut from regular crystallographic faces, any polytype, mixed polytype, doped, undoped, polycrystalline, amorphous, cubic, or hexagonal symmetry.

In some embodiments, the oxidizer may control the face selectivity of the silicon carbide substrate. In some embodiments, the face selectivity is a silicon face of the silicon carbide substrate. In some embodiments, the face selectivity is a carbon face of the silicon carbide.

At step 104, in some embodiments, the method comprises polishing the silicon carbide substrate, while the composition is located between a polishing pad and the silicon carbide substrate. In some embodiments, the method comprises polishing a silicon face of the silicon carbide substrate, while the composition is located between a polishing pad and the silicon carbide substrate. In some embodiments, the method comprises polishing a carbon face of the silicon carbide substrate, while the composition is located between a polishing pad and the silicon carbide substrate. In some embodiments, the polishing comprises rotating the pad with the composition located between the pad and the silicon carbide substrate. In some embodiments, the polishing comprises applying a force via the pad with the composition located between the pad and the silicon carbide substrate.

The pad may comprise a woven pad and/or a non-woven pad. A pad may comprise a polymer of varying density, hardness, thickness, compressibility, have an ability to rebound upon compression, and compression modulus. In some embodiments, the polymer comprises at least one of polyvinylchloride, polyvinyl fluoride, nylon, fluorocarbon, polycarbonate, polyester, polyacrylate, polyether, polyethylene, polyamide, polyurethane, polystyrene, polypropylene, or any combination thereof. In some embodiments, the pad has a circular shape and, when in use, may have a rotational motion about an axis perpendicular to the plane defined by the surface of the pad. In some embodiments, the pad has a cylindrical shape, the surface of which acts as the polishing surface, and, when in use, may have a rotational motion about the central axis of the cylinder. In some embodiments, the pad is provided in a form of an endless belt, which, when in use, may have a linear motion with respect to the cutting edge being polished. In some embodiments, when in use, the pad has a reciprocating or orbital motion along a plane or a semicircle. In some embodiments the polishing is sufficient to result in an increase in a material removal rate relative to a control composition, wherein the control composition does not comprise the at least one rare earth metal salt compound.

In some embodiments, the polishing is conducted at a material removal rate of 1 μm/hr to 15 μm/hr, or any range or subrange between 1 μm/hr and 15 μm/hr. In some embodiments, for example, the polishing is conducted at a material removal rate of 2 μm/hr to 14 μm/hr, 3 μm/hr to 13 μm/hr, 4 μm/hr to 12 μm/hr, 5 μm/hr to 11 μm/hr, 6 μm/hr to 10 μm/hr, or 7 μm/hr to 9 μm/hr. In some embodiments, the polishing is conducted at a material removal rate of 1 μm/hr to 14 μm/hr, 1 μm/hr to 13 μm/hr, 1 μm/hr to 12 μm/hr, 1 μm/hr to 11 μm/hr, 1 μm/hr to 10 μm/hr, 1 μm/hr to 9 μm/hr, 1 μm/hr to 8 μm/hr, 1 μm/hr to 7 μm/hr, 1 μm/hr to 6 μm/hr, 1 μm/hr to 5 μm/hr, 1 μm/hr to 4 μm/hr, 1 μm/hr to 3 μm/hr, or 1 μm/hr to 2 μm/hr. In some embodiments, the polishing is conducted at a material removal rate of 2 μm/hr to 15 μm/hr, 3 μm/hr to 15 μm/hr, 4 μm/hr to 15 μm/hr, 5 μm/hr to 15 μm/hr, 6 μm/hr to 15 μm/hr, 7 μm/hr to 15 μm/hr, 8 μm/hr to 15 μm/hr, 9 μm/hr to 15 μm/hr, 10 μm/hr to 15 μm/hr, 11 μm/hr to 15 μm/hr, 12 μm/hr to 15 μm/hr, 13 μm/hr to 15 μm/hr, or 14 μm/hr to 15 μm/hr.

Some embodiments relate to a system. In some embodiments, the system comprises a silicon carbide substrate. In some embodiments, the system comprises a composition. It will be appreciated that any one or more of the silicon carbide substrates and/or compositions disclosed herein may be employed, without departing from the scope of this disclosure. For example, in some embodiments, the composition comprises an oxidizer, a plurality of particles, and 0.01% to 5% by weight of at least one rare earth metal salt compound based on a total weight of the composition.

In some embodiments, the oxidizer comprises at least one of a potassium permanganate, a sodium permanganate, a lithium permanganate, a barium permanganate, a hydrogen permanganate, a sodium chlorate, an aluminum perchlorate, or any combination thereof.

In some embodiments, the at least one rare earth metal salt compound comprises at least one of a rare earth metal oxide compound, a rare earth metal nitrate compound, a rare earth metal oxynitrate compound, or any combination thereof.

In some embodiments, the composition further comprises 0.01% to 5% by weight of at least one metal salt compound based on the total weight of the composition.

In some embodiments, the system comprises a chemical mechanical planarization apparatus. In some embodiments, the chemical mechanical planarization apparatus is configured to bring the composition into contact with the silicon carbide substrate and a polishing pad to remove at least a portion of the silicon carbide substrate.

In some embodiments, the contact comprises bringing the composition into immediate or close proximity with the silicon carbide substrate. In some embodiments, the contact comprises bringing the composition into direct physical contact with the silicon carbide substrate. In some embodiments, the contact comprises coating the composition on the silicon carbide substrate. In some embodiments, the contact comprises spin-coating the composition onto the silicon carbide substrate. In some embodiments, the contact comprises casting the composition onto the silicon carbide substrate. In some embodiments, the contact comprises pouring the composition onto the silicon carbide substrate. In some embodiments, the contact comprises soaking the silicon carbide substrate in the composition. In some embodiments, the contact comprises immersing the silicon carbide substrate in the composition. In some embodiments, the contact comprises placing the silicon carbide substrate in a bath comprising the composition.

In some embodiments, the contact is performed under conditions sufficient to result in an increase in a material removal rate relative to a control composition. In some embodiments, the contact is performed at a temperature of 25° C. to 100° C., or any range or subrange between 25° C. and 100° C. In some embodiments, the contacting is performed at a temperature of 25° C. to 100° C., 25° C. to 90° C., 25° C. to 80° C., 25° C. to 70° C., 25° C. to 60° C., 25° C. to 50° C., 25° C. to 40° C., 25° C. to 30° C., 30° C. to 100° C., 40° C. to 100° C., 50° C. to 100° C., 60° C. to 100° C., 70° C. to 100° C., 80° C. to 100° C., or 90° C. to 100° C. The temperature can be selected to accelerate a material removal rate of a silicon carbide layer.

In some embodiments, the contact is performed for a duration of 1 minute to 24 hours, or any range or subrange between 1 minute and 24 hours. In some embodiments, the contact is performed for a duration of 1 minute to 24 hours, 1 minute to 20 hours, 1 minute to 15 hours, 1 minute to 10 hours, 1 minute to 9 hours, 1 minute to 8 hours, 1 minute to 7 hours, 1 minute to 6 hours, 1 minute to 5 hours, 1 minute to 4 hours, 1 minute to 3 hours, 1 minute to 2 hours, 1 minute to 1 hour, 1 minute to 60 minutes, 1 minute to 50 minutes, 1 minute to 40 minutes, 1 minute to 30 minutes, 1 minute to 20 minutes, 1 minute to 10 minutes, 1 minute to 5 minutes, 1 hour to 24 hours, 5 hours to 24 hours, 10 hours to 24 hours, 15 hours to 24 hours, or 20 hours to 24 hours. In some embodiments, when the composition is applied to a silicon carbide substrate and when the chemical mechanical planarization apparatus is operated, the silicon carbide substrate is polished at a material removal rate of 1 μm/hr to 15 μm/hr.

Any one or more of the embodiments disclosed herein shall be understood to be combinable without departing from the scope or spirit of the disclosure.

### Example 1

Various compositions for polishing silicon carbide wafers were prepared and the performance of each was evaluated. Control Sample 1 is a commercially available composition. Control Sample 1 comprises an oxidizer, a plurality of particles, and 0.35 wt. % of zirconium oxynitrate. The compositions of Samples 2-5 are summarized in the Table 1 below. Silicon faces of 4″ diameter silicon carbide (SiC) wafers were polished with Control Sample 1 and Samples 2-5. Each wafer was contacted with each Sample using a commercially available pad for a duration of 10 minutes at a carrier speed of 117 rotations per minute (RPM) and platen speed of 123 RPM. During polishing, each sample was supplied at a slurry flow rate of 50 milliliter per minute (mL/min), with 7 PSI of pressure being applied to each wafer. Table 2 below summarizes the polishing conditions.

TABLE 1
Samples 2-5 Composition

| | NaMnO₄ | Zirconia | Booster | |
|---|---|---|---|---|
| | (wt. %) | (wt. %) | (wt. %) | pH |
| Sample 2 | 8 | 0.5 | 0.9 Nd(NO₃)₃ | 2.3 |
| Sample 3 | 8 | 0.5 | 0.9 La(NO₃)₃ | 2.3 |
| Sample 4 | 8 | 0.5 | 0.8 La(NO₃)₃ | 2.3 |
| Sample 5 | 8 | 0.5 | 0.4 La(NO₃)₃ | 2.0 |

TABLE 2
Polishing Conditions

| | | |
|---|---|---|
| Wafer Pressure | 7 | psi |
| Carrier/Platen Speed | 117/123 | RPM |
| Polishing Time | 10 | min |
| Composition Flow Rate | ~50 | mL/min |

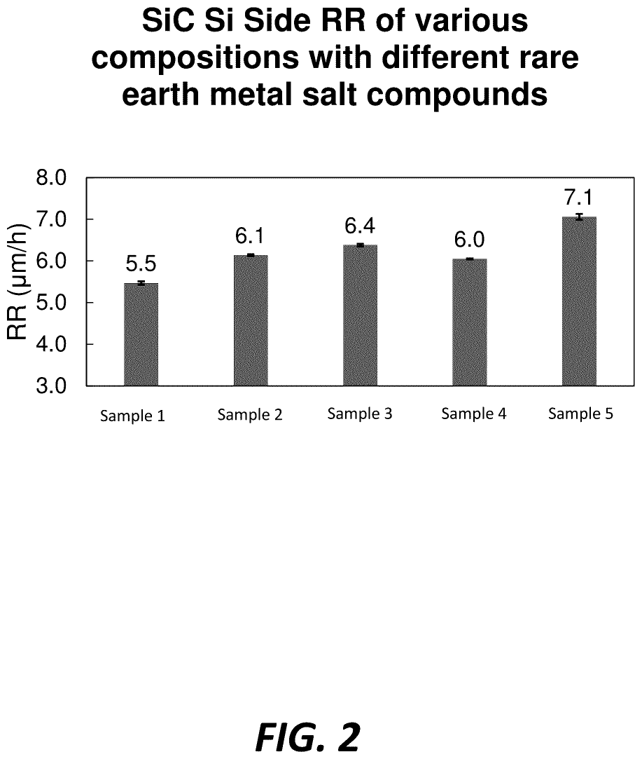

FIG. 2 is a graphical view illustrating the material removal rate using various compositions having different rare earth metal salt compounds, according to some embodiments. As shown in FIG. 2, Samples 2-5 had an increase in a material removal rate relative to the control composition.

### Example 2

Various compositions using different La(NO₃)₃ concentrations were prepared and the performance of each was evaluated. The compositions are summarized in the Table 3 below as Samples 6-9. Silicon faces of 4″ diameter SiC wafers were polished with Samples 6-9. Each wafer was contacted with each sample using a commercially available pad for a duration of 10 minutes at a carrier speed of 117 RPM and platen speed of 123 RPM. During polishing, each sample was supplied at a slurry flow rate of 50 mL/min, with 7 PSI of pressure being applied to each wafer. Table 2 summarizes the polishing conditions.

TABLE 3
Samples 6-9 Composition

| | | | Rare Earth Metal | |
|---|---|---|---|---|
| | NaMnO₄ | Zirconia | Salt Compound | |
| | (wt. %) | (wt. %) | (wt. %) | pH |
| Sample 6 | 8 | 0.5 | 0.1 La(NO₃)₃ | 2.3 |
| Sample 7 | 8 | 0.5 | 0.4 La(NO₃)₃ | 2.3 |
| Sample 8 | 8 | 0.5 | 0.6 La(NO₃)₃ | 2.3 |
| Sample 9 | 8 | 0.5 | 0.9 La(NO₃)₃ | 2.3 |

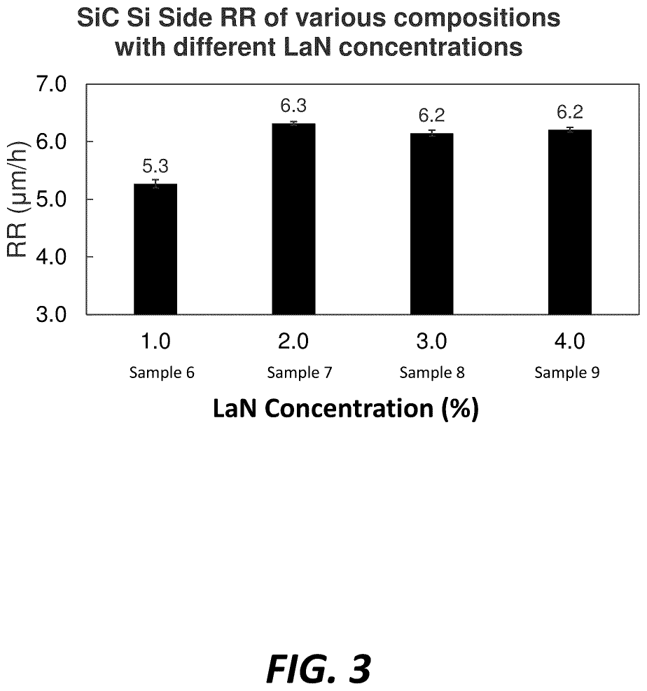

FIG. 3 is a graphical view illustrating the material removal rate using various concentrations of lanthanum nitrate, according to some embodiments. As shown in FIG. 3, Sample 7 with a 0.35 wt. % concentration of La(NO₃)₃ had highest material removal rate.

### Example 3

Various compositions using different concentrations of rare earth metal salt compounds and metal salt compounds were prepared and the performance of each was evaluated. The compositions are summarized in the Table 4 below as Samples 10-21. Silicon faces of 4″ diameter SiC wafers were polished with Samples 10-21. Each wafer was contacted with each sample using a commercially available pad for a duration of 10 minutes at a carrier speed of 105 RPM and platen speed of 115 RPM. During polishing, each sample was supplied at a slurry flow rate of 50 mL/min, with 5 PSI of pressure being applied to each wafer. Sample 10 was the control composition. The control composition did not comprise at least one of a metal salt compound, a rare earth metal salt compound, or any combination thereof. Table 5 summarizes the polishing conditions.

TABLE 4
Samples 10-21 Composition

| | | | Metal Salt | |
|---|---|---|---|---|
| | | | Compound/Rare | |
| | KMnO₄ | Zirconia | Earth Metal Salt | |
| | (wt. %) | (wt. %) | Compound (wt. %) | pH |
| Sample 10 | 2.2 | 0.5 | 0 | 1.9 |
| Sample 11 | 2.2 | 0.5 | 0.5 ZrO(NO₃)₂ | 2.5 |
| Sample 12 | 2.2 | 0.5 | 0.8 Y(NO₃)₃ | 2.8 |
| Sample 13 | 2.2 | 0.5 | 0.9 La(NO₃)₃ | 2.7 |
| Sample 14 | 2.2 | 0.5 | 0.8 Y(NO₃)₃ | 2.0 |
| Sample 15 | 2.2 | 0.5 | 0.8 Ga(NO₃)₃ | 1.9 |
| Sample 16 | 2.2 | 0.5 | 0.8 In(NO₃)₃ | 2.0 |
| Sample 17 | 2.2 | 0.5 | 0.8 Fe(NO₃)₃ | 2.2 |
| Sample 18 | 2.2 | 0.5 | 0.8 Cr(NO₃)₃ | 1.7 |
| Sample 19 | 2.2 | 0.5 | 0.3 AgNO₃ | 1.7 |
| Sample 20 | 2.2 | 0.5 | 0.6 Zn(NO₃)₂ | 2.0 |
| Sample 21 | 2.2 | 0.5 | 0.8 Ce(NO₃)₃ | 1.9 |

TABLE 5
Polishing Conditions

| | | |
|---|---|---|
| Wafer Pressure | 5 | psi |
| Carrier/Platen Speed | 105/115 | RPM |
| Polishing Time | 10 | min |
| Composition Flow Rate | ~50 | mL/min |

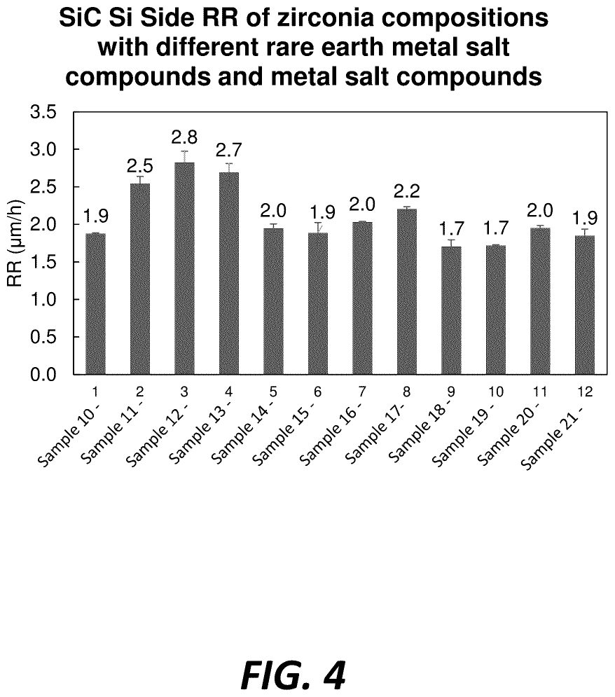

FIG. 4 is a graphical view illustrating the material removal rate using zirconia compositions having different concentrations of the different rare earth metal salt compounds and metal salt compounds, according to some embodiments.

### Example 4

Various compositions using different concentrations of alumina with different rare earth metal salt compounds and metal salt compounds were prepared and the performance of each was evaluated. The compositions are summarized in the Table 6 below as Samples 22-24. Silicon faces of 4″ diameter SiC wafers were polished with Samples 22-24. Each wafer was contacted with each sample using a commercially available pad for a duration of 10 minutes at a carrier speed of 105 RPM and platen speed of 115 RPM. During polishing, each sample was supplied at a slurry flow rate of 50 mL/min, with 5 PSI of pressure being applied to each wafer. Sample 22 was the control composition. The control composition did not comprise at least one of a metal salt compound, a rare earth metal salt compound, or any combination thereof. Table 5 summarizes the polishing conditions.

TABLE 6
Samples 22-24 Composition

| | | | Metal Salt | |
|---|---|---|---|---|
| | | | Compound/Rare | |
| | NaMnO₄ | Alumina | Earth Metal Salt | |
| | (wt. %) | (wt. %) | Compound (wt. %) | pH |
| Sample 22 | 8 | 1 | 0 | 3.7 |
| Sample 23 | 8 | 1 | 0.4 ZrO(NO₃)₂ | 3.7 |
| Sample 24 | 8 | 1 | 0.9 La(NO₃)₃ | 3.7 |

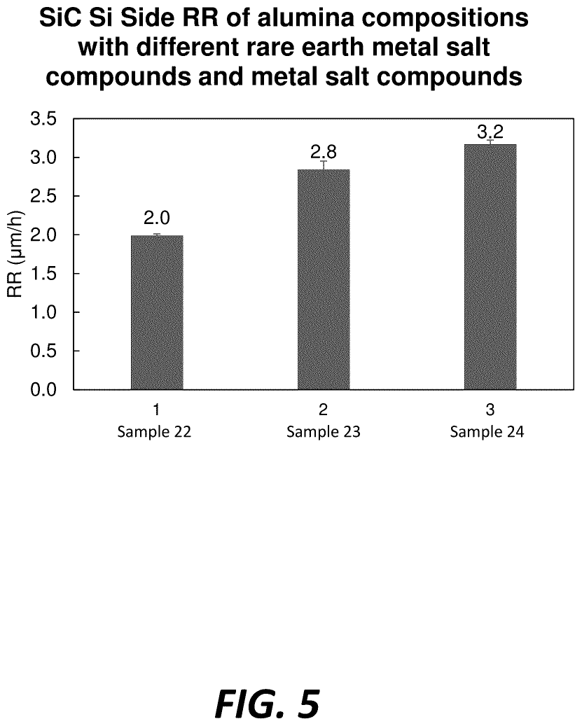

FIG. 5 is a graphical view illustrating the material removal rate using alumina compositions having different rare earth metal salt compounds and metal salt compounds, according to some embodiments.

### Example 5

Various compositions for polishing silicon carbide wafers were prepared and the performance of each was evaluated. The compositions are summarized in the Table 7 below as Samples 25-26. Silicon faces of 4″ diameter SiC wafers were polished with Samples 25-26. Each wafer was contacted with each sample using a commercially available pad for a duration of 10 minutes at a carrier speed of 117 RPM and platen speed of 123 RPM. During polishing, each sample was supplied at a slurry flow rate of 50 mL/min, with 7 PSI of pressure being applied to each wafer. Sample 25 was the control composition. The control composition did not comprise at least one of a metal salt compound, a rare earth metal salt compound, or any combination thereof. Table 3 summarizes the polishing conditions.

TABLE 7
Samples 25-26 Composition

| | | | Metal Salt | |
|---|---|---|---|---|
| | NaMnO₄ | Ceria | Compound | |
| | (wt. %) | (wt. %) | (wt. %) | pH |
| Sample 25 | 8 | 1 | 0 | 2.3 |
| Sample 26 | 8 | 1 | 0.4 La(NO₃)₃ | 2.3 |

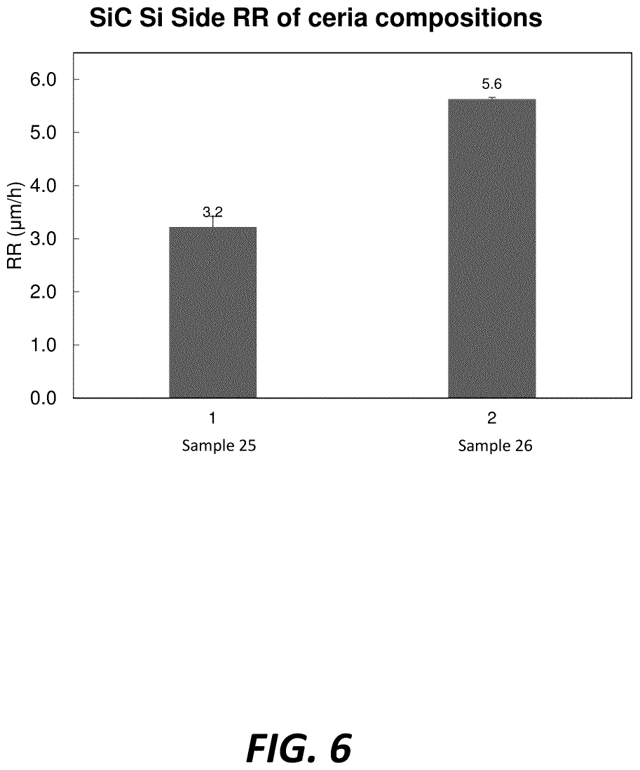

FIG. 6 is a graphical view illustrating the material removal rate using Ceria, according to some embodiments.

### Example 6

Various silica compositions having rare earth metal salt compounds and metal salt compounds for polishing silicon carbide wafers were prepared and the performance of each was evaluated. The compositions are summarized in the Table 8 below as Samples 27-29. Silicon faces of 4″ diameter SiC wafers were polished with Samples 27-29. Each wafer was contacted with each sample using a commercially available pad for a duration of 10 minutes at a carrier speed of 117 RPM and platen speed of 123 RPM. During polishing, each sample was supplied at a slurry flow rate of 50 mL/min, with 7 PSI of pressure being applied to each wafer. Sample 27 was the control composition. The control composition did not comprise at least one of a metal salt compound, a rare earth metal salt compound, or any combination thereof. Table 2 summarizes the polishing conditions.

TABLE 8
Samples 27-29 Composition

| | | Coated | Rare Earth Metal | Metal Salt | |
|---|---|---|---|---|---|
| | NaMnO₄ | Silica | Salt Compound | Compound | |
| | (wt. %) | (wt. %) | (wt. %) | (wt. %) | pH |
| Sample 27 | 8 | 1 | 0 | 0.8 Al(NO₃)₃ | 2.3 |
| Sample 28 | 8 | 1 | 0.4 La(NO₃)₃ | 0.8 Al(NO₃)₃ | 2.3 |
| Sample 29 | 8 | 1 | 0.2 La(NO₃)₃ | 0.2 ZrO(NO₃)₂ | 2.3 |

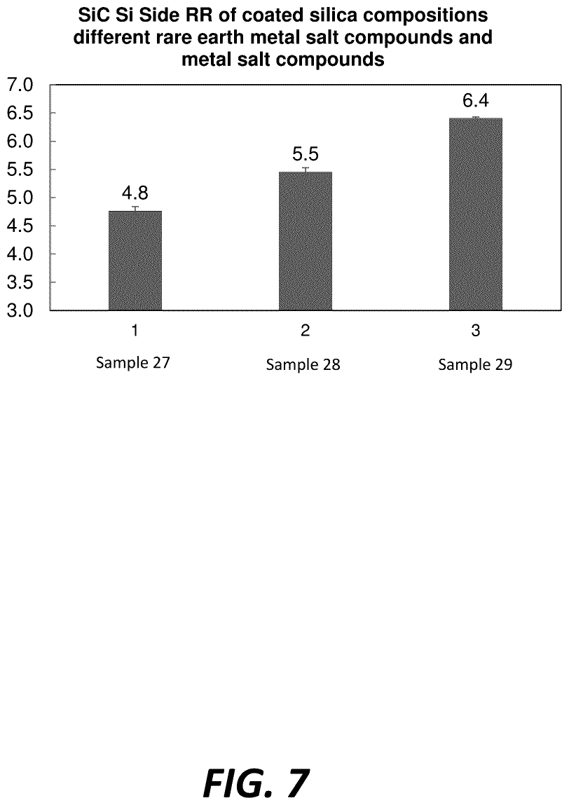

FIG. 7 is a graphical view illustrating the material removal rate using Silica compositions having different rare earth metal salt compounds and metal salt compounds, according to some embodiments.

### Example 7

Various compositions using different concentrations rare earth metal salt compounds and metal salt compounds were prepared and the performance of each was evaluated. The compositions are summarized in the Table 9 below as Samples 30-34. Silicon faces of SiC wafers were polished with Samples 30-34. Each wafer was contacted with each sample using a PWR1000 pad for a duration of 10 minutes at a carrier speed of 105 RPM and platen speed of 115 RPM. During polishing, each sample was supplied at a slurry flow rate of 50 mL/min, with 5 PSI of pressure being applied to each wafer. Sample 1 was the control composition. The control composition did not comprise at least one of a metal salt compound, a rare earth metal salt compound, or any combination thereof. Table 5 summarizes the polishing conditions.

TABLE 9
Samples 30-34 Composition

| | | Metal Salt | | |
|---|---|---|---|---|
| | | Compound/Rare | | |
| | NaMnO₄ | Earth Metal Salt | | Eₚ |
| | (wt. %) | Compound (wt. %) | pH | (mV) |
| Sample 30 | 2.2 | 0 | 2.3 | 0.6 |
| Sample 31 | 2.2 | 0.4 ZrO(NO₃)₂ | 2.3 | 0.5 |
| Sample 32 | 2.2 | 0.8 Al(NO₃)₃ | 2.3 | 0.6 |
| Sample 33 | 2.2 | 0.9 La(NO₃)₃ | 2.3 | 0.6 |
| Sample 34 | 2.2 | 0.8 Y(NO₃)₃ | 2.3 | 0.6 |

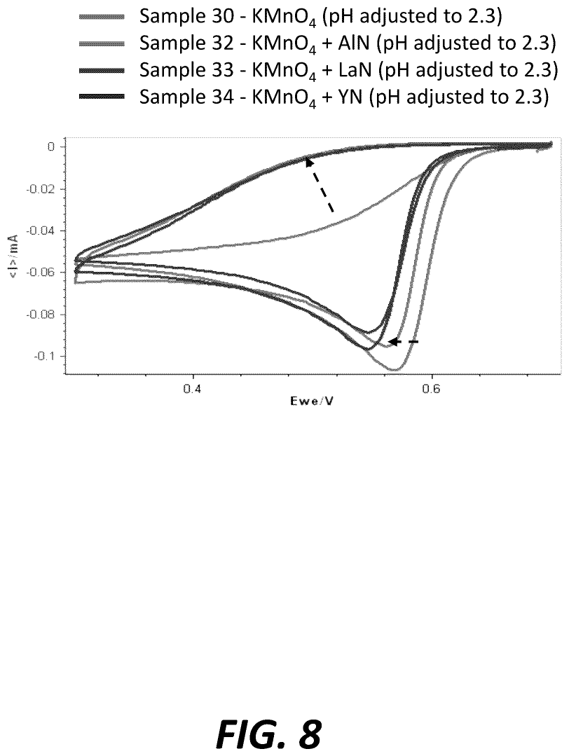

FIG. 8 is a graphical view illustrating permanganate reduction using various compositions having different rare earth metals, according to some embodiments. As shown FIG. 8, the addition of the rare earth metal salt compounds and metal salt compounds reduces the reduction peak Ep of the oxidizer, for example, NaMNO₄ to negative, which increases the material removal rate.

### Example 8

Various compositions using different concentrations rare earth metal salt compounds and metal salt compounds were prepared and the performance of each was evaluated. The compositions are summarized in the Table 10 below as Samples 35-38. Silicon faces of 4″ diameter SiC wafers were polished with Samples 35-38. Each wafer was contacted with each sample using a commercially available pad for a duration of 10 minutes at a carrier speed of 105 RPM and platen speed of 115 RPM. During polishing, each sample was supplied at a slurry flow rate of 50 mL/min, with 5 PSI of pressure being applied to each wafer. Sample 35 was a control composition. The control composition did not comprise at least one of a metal salt compound, a rare earth metal salt compound, or any combination thereof. Table 5 summarizes the polishing conditions.

TABLE 10
Samples 35-38 Composition

| | | | Rare Earth | | | | |
|---|---|---|---|---|---|---|---|
| | | | Metal Salt | Metal Salt | pH at | pH at | Material |
| | NaMnO₄ | Zirconia | Compound | Compound | week | week | Removal |
| | (wt. %) | (wt. %) | (wt. %) | (wt. %) | 0 | 8 | Rate |
| Sample | 8 | 0.5 | 0 | 0 | 2.2 | 2.1 | 5.3 |
| 35 | | | | | | | |
| Sample | 8 | 0.5 | 0.4 | 0 | 2.0 | 2.5 | 6.1 |
| 36 | | | La(NO₃)₃ | | | | |
| Sample | 8 | 0.5 | 0.4 | 0.4 | 2.0 | 2.1 | 5.8 |
| 37 | | | La(NO₃)₃ | ZrO(NO₃)₂ | | | |
| Sample | 8 | 0.5 | 0.4 | 0.2 | 2.0 | 2.0 | 6.3 |
| 38 | | | La(NO₃)₃ | Fe(NO₃)₃ | | | |

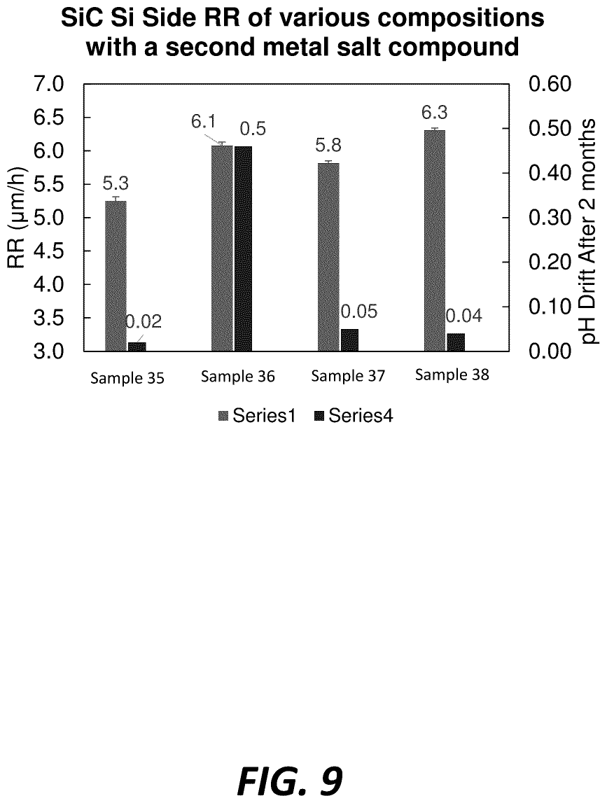

FIG. 9 is a graphical view illustrating buffering effect using various compositions having a second metal salt compound, according to some embodiments.

### Example 9

Various compositions using different concentrations of rare earth metal salt compounds and metal salt compounds were prepared and the performance of each was evaluated. The compositions and performance are summarized in Table 11 and Table 12 below as Samples 39-42. Silicon faces and carbon faces of 4″ diameter SiC wafers were polished using Mirra. Each wafer was contacted with each sample using a commercially available pad for a duration of 10 minutes at a carrier speed of 117 RPM and platen speed of 123 RPM. During polishing, each sample was supplied at a slurry flow rate of 50 milliliter per minute (mL/min), with 7 PSI of pressure being applied to each wafer. Sample 39 was a control composition. The control composition did not comprise a plurality of particles. The control composition comprised a metal salt compound. Table 2 summarizes the polishing conditions.

TABLE 11
Samples 39-42 Composition

| | | | Rare Earth | | | |
|---|---|---|---|---|---|---|
| | | | Metal Salt | Metal Salt | Metal Salt | |
| | NaMnO₄ | Zirconia | Compound | Compound | Compound | |
| | (wt. %) | (wt. %) | (wt. %) | (wt. %) | (wt. %) | pH |
| Sample | 14 | 0 | 1% | 0.4% | 0 | 2.0 |
| 39 | | | La(NO₃)₃ | ZrO(NO₃)₂ | | |
| Sample | 14 | 0 | 1% | 0.4% | 1% | 2.0 |
| 40 | | | La(NO₃)₃ | ZrO(NO₃)₂ | Al(NO₃)₃ | |
| Sample | 14 | 0.25 | 1% | 0.4% | 0 | 2.0 |
| 41 | | | La(NO₃)₃ | ZrO(NO₃)₂ | | |
| Sample | 14 | 0.25 | 1% | 0.4% | 1% | 2.0 |
| 42 | | | La(NO₃)₃ | ZrO(NO₃)₂ | Al(NO₃)₃ | |

TABLE 12
Samples 39-42 Material Removal Rate

| | Si side | C side | Lasertec | Candela |
|---|---|---|---|---|
| | MRR | MRR | Haze C | Haze Si |
| | (μm/h) | (μm/h) | side | side |
| Sample 39 | 6.6 | 21.8 | 42.1 | 435.0 |
| Sample 40 | 7.2 | 25.5 | 35.8 | 424.0 |
| Sample 41 | 6.9 | 22.1 | 44.7 | 436.2 |
| Sample 42 | 7.4 | 23.7 | 43.4 | 427.0 |

As shown Table 12, the addition of a third metal salt compound in the composition increases the material removal rate on the silicon face and carbon face of the silicon carbide wafer. The surface quality on the silicon face and carbon face of the silicon wafer improves as the Haze value decreases.

### Example 10

Various compositions using abrasive-free particles having rare earth metal salt compounds and metal salt compounds were prepared and the performance of each was evaluated. The compositions are summarized in the Table 13 below as Samples 43-47. Silicon faces of 4″ diameter SiC wafers were polished with Samples 43-47. Each wafer was contacted with each sample using a commercially available pad for a duration of 10 minutes at a carrier speed of 117 RPM and platen speed of 123 RPM. During polishing, each sample was supplied at a slurry flow rate of 50 mL/min, with 7 PSI of pressure being applied to each wafer. Sample 43 was the control composition. The control composition did not comprise at least one of a metal salt compound, a rare earth metal salt compound, or any combination thereof. Table 2 summarizes the polishing conditions.

TABLE 13
Samples 43-47 Composition

| | | Rare Earth | | | |
|---|---|---|---|---|---|
| | | Metal Salt | Metal Salt | Metal Salt | |
| | NaMnO₄ | Compound | Compound | Compound | |
| | (wt. %) | (wt. %) | (wt. %) | (wt. %) | pH |
| Sample | 6 | 0 | 0 | 0 | 2.0 |
| 43 | | | | | |
| Sample | 6 | 0.4 | 0 | 0 | 2.0 |
| 44 | | La(NO₃)₃ | | | |
| Sample | 6 | 0.4 | 0.4 | 0 | 2.0 |
| 45 | | La(NO₃)₃ | Al(NO₃)₃ | | |
| Sample | 6 | 0.2 | 0 | 0.2 | 2.0 |
| 46 | | La(NO₃)₃ | | Zn(NO₃)₂ | |
| Sample | 6 | 0.2 | 0.4 | 0.2 | 2.0 |
| 47 | | La(NO₃)₃ | Al(NO₃)₃ | Zn(NO₃)₂ | |

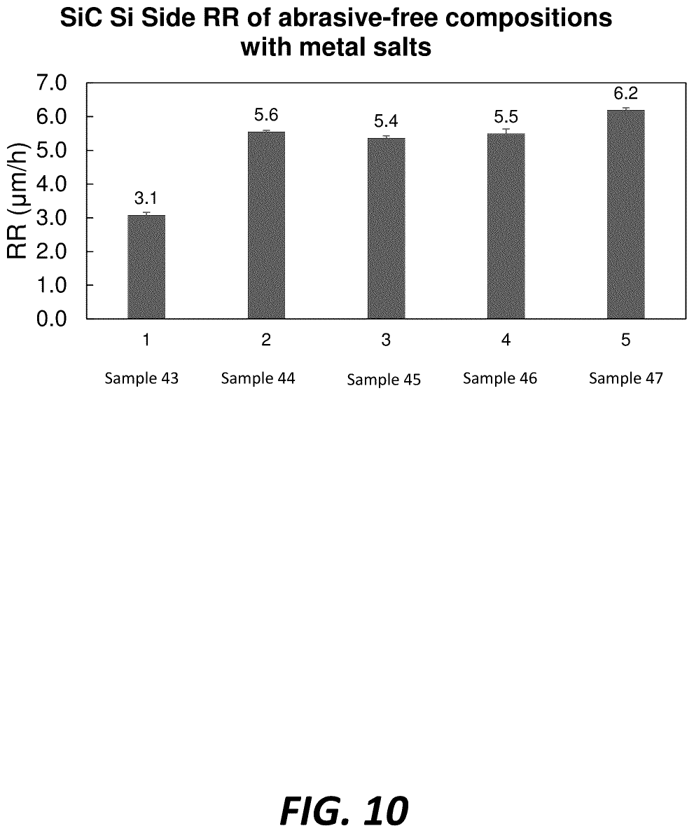

FIG. 10 is a graphical view illustrating the material removal rate using abrasive-free compositions having different rare earth metal salt compounds and metal salt compounds, according to some embodiments.

Any one or more of the embodiments disclosed herein shall be understood to be combinable without departing from the scope or spirit of the disclosure.

### ASPECTS

Various Aspects are described below. It is to be understood that any one or more of the features recited in the following Aspect(s) can be combined with any one or more other Aspect(s).

Various Aspects are described below. It is to be understood that any one or more of the features recited in the following Aspect(s) can be combined with any one or more other Aspect(s).
Aspect 1. A composition comprising:
   an oxidizer;
   a plurality of particles; and
   0.01% to 5% by weight of at least one rare earth metal salt compound based on a total weight of the composition,
      wherein, when the composition is applied to a silicon carbide substrate and when the silicon carbide substrate is polished, the at least one rare earth metal salt compound is present in an amount sufficient to result in an increase in a material removal rate relative to a control composition, wherein the control composition does not comprise the at least one rare earth metal salt compound.
Aspect 2. The composition according to Aspect 1, wherein the oxidizer comprises at least one of a potassium permanganate, a sodium permanganate, a lithium permanganate, a barium permanganate, a hydrogen permanganate, a sodium chlorate, an aluminum perchlorate, or any combination thereof.
Aspect 3. The composition according to any one of Aspects 1-2, wherein the plurality of particles comprises at least one of an alumina, a boehmite, a zirconia, a ceria, a silica, an abrasive-free particle, or any combination thereof.
Aspect 4. The composition according to any one of Aspects 1-3, wherein the composition comprises 0.01% to 1% by weight of the at least one rare earth metal salt compound based on the total weight of the composition.
Aspect 5. The composition according to any one of Aspects 1-4, wherein the at least one rare earth metal salt compound comprises at least one of a rare earth metal oxide compound, a rare earth metal nitrate compound, a rare earth metal oxynitrate compound, or any combination thereof.
Aspect 6. The composition according to any one of Aspects 1-5, further comprising 0.01% to 5% by weight of at least one metal salt compound based on the total weight of the composition.
Aspect 7. The composition according to any one of Aspects 1-6, further comprising a pH adjuster.
Aspect 8. The composition according to any one of Aspects 1-7, wherein the composition has a pH 1 to 10, when measured at 25° C. and 1 atm.
Aspect 9. A method comprising:
   dispensing a composition onto a silicon carbide substrate,
      wherein the composition comprises:
         an oxidizer;
         a plurality of particles; and
         0.01% to 5% by weight of at least one rare earth metal salt compound based on a total weight of the composition; and
   polishing the silicon carbide substrate, while the composition is located between a polishing pad and the silicon carbide substrate,
      wherein the polishing is sufficient to result in an increase in a material removal rate relative to a control composition, wherein the control composition does not comprise the at least one rare earth metal salt compound.
Aspect 10. The method according to Aspect 9, wherein the polishing is conducted at a material removal rate of 1 μm/hr to 15 μm/hr.
Aspect 11. The method according to any one of Aspects 9-10, wherein the oxidizer comprises at least one of a potassium permanganate, a sodium permanganate, a lithium permanganate, a barium permanganate, a hydrogen permanganate, a sodium chlorate, an aluminum perchlorate, or any combination thereof.
Aspect 12. The method according to any one of Aspects 9-11, wherein the plurality of particles comprises at least one of an alumina, a boehmite, a zirconia, or any combination thereof.
Aspect 13. The method according to any one of Aspects 9-12, wherein the at least one rare earth metal salt compound comprises at least one of a rare earth metal oxide compound, a rare earth metal nitrate compound, a rare earth metal oxynitrate compound, or any combination thereof.
Aspect 14. The method according to any one of Aspects 9-13, wherein the composition further comprises 0.01% to 5% by weight of at least one metal salt compound based on the total weight of the composition.
Aspect 15. The method according to any one of Aspects 9-14, wherein the composition has a pH 1 to 10, when measured at 25° C. and 1 atm.
Aspect 16. A system comprising:
   a silicon carbide substrate;
   a composition,
      wherein the composition comprises:
         an oxidizer;
         a plurality of particles; and
         0.01% to 5% by weight of at least one rare earth metal salt compound based on a total weight of the composition; and
   a chemical mechanical planarization apparatus,
      wherein the chemical mechanical planarization apparatus is configured to bring the composition into contact with the silicon carbide substrate and a polishing pad to remove at least a portion of the silicon carbide substrate.
Aspect 17. The system according to Aspect 16, wherein, when the composition is applied to a silicon carbide substrate and when the chemical mechanical planarization apparatus is operated, the silicon carbide substrate is polished at a material removal rate of 1 μm/hr to 15 μm/hr.
Aspect 18. The system according to any one of Aspects 16-17, wherein the oxidizer comprises at least one of a potassium permanganate, a sodium permanganate, a lithium permanganate, a barium permanganate, a hydrogen permanganate, a sodium chlorate, an aluminum perchlorate, or any combination thereof.
Aspect 19. The system according to any one of Aspects 16-18, wherein the at least one rare earth metal salt compound comprises at least one of a rare earth metal oxide compound, a rare earth metal nitrate compound, a rare earth metal oxynitrate compound, or any combination thereof.
Aspect 20. The system according to any one of Aspects 16-19, wherein the composition further comprises 0.01% to 5% by weight of at least one metal salt compound based on the total weight of the composition.

What is claimed is:

1. A composition comprising:
an oxidizer;
a plurality of particles; and
0.01% to 5% by weight of at least one rare earth metal salt compound based on a total weight of the composition,
wherein, when the composition is applied to a silicon carbide substrate and when the silicon carbide substrate is polished, the at least one rare earth metal salt compound is present in an amount sufficient to result in an increase in a material removal rate relative to a control composition, wherein the control composition does not comprise the at least one rare earth metal salt compound.

2. The composition of claim 1, wherein the oxidizer comprises at least one of a potassium permanganate, a sodium permanganate, a lithium permanganate, a barium permanganate, a hydrogen permanganate, a sodium chlorate, an aluminum perchlorate, or any combination thereof.

3. The composition of claim 1, wherein the plurality of particles comprises at least one of an alumina, a boehmite, a zirconia, a ceria, a silica, an abrasive-free particle, or any combination thereof.

4. The composition of claim 1, wherein the composition comprises 0.01% to 1% by weight of the at least one rare earth metal salt compound based on the total weight of the composition.

5. The composition of claim 1, wherein the at least one rare earth metal salt compound comprises at least one of a rare earth metal oxide compound, a rare earth metal nitrate compound, a rare earth metal oxynitrate compound, or any combination thereof.

6. The composition of claim 1, further comprising 0.01% to 5% by weight of at least one metal salt compound based on the total weight of the composition.

7. The composition of claim 1, further comprising a pH adjuster.

8. The composition of claim 1, wherein the composition has a pH 1 to 10, when measured at 25° C. and 1 atm.

9. A method comprising:
dispensing a composition onto a silicon carbide substrate,
wherein the composition comprises:
an oxidizer;
a plurality of particles; and
0.01% to 5% by weight of at least one rare earth metal salt compound based on a total weight of the composition; and
polishing the silicon carbide substrate, while the composition is located between a polishing pad and the silicon carbide substrate,
wherein the polishing is sufficient to result in an increase in a material removal rate relative to a control composition, wherein the control composition does not comprise the at least one rare earth metal salt compound.

10. The method of claim 9, wherein the polishing is conducted at a material removal rate of 1 μm/hr to 15 μm/hr.

11. The method of claim 9, wherein the oxidizer comprises at least one of a potassium permanganate, a sodium permanganate, a lithium permanganate, a barium permanganate, a hydrogen permanganate, a sodium chlorate, an aluminum perchlorate, or any combination thereof.

12. The method of claim 9, wherein the plurality of particles comprises at least one of an alumina, a boehmite, a zirconia, or any combination thereof.

13. The method of claim 9, wherein the at least one rare earth metal salt compound comprises at least one of a rare earth metal oxide compound, a rare earth metal nitrate compound, a rare earth metal oxynitrate compound, or any combination thereof.

14. The method of claim 9, wherein the composition further comprises 0.01% to 5% by weight of at least one metal salt compound based on the total weight of the composition.

15. The method of claim 9, wherein the composition has a pH 1 to 10, when measured at 25° C. and 1 atm.

16. A system comprising:
a silicon carbide substrate;
a composition,
wherein the composition comprises:
an oxidizer;
a plurality of particles; and
0.01% to 5% by weight of at least one rare earth metal salt compound based on a total weight of the composition; and
a chemical mechanical planarization apparatus,
wherein the chemical mechanical planarization apparatus is configured to bring the composition into contact with the silicon carbide substrate and a polishing pad to remove at least a portion of the silicon carbide substrate.

17. The system of claim 16, wherein, when the composition is applied to a silicon carbide substrate and when the chemical mechanical planarization apparatus is operated, the silicon carbide substrate is polished at a material removal rate of 1 μm/hr to 15 μm/hr.

18. The system of claim 16, wherein the oxidizer comprises at least one of a potassium permanganate, a sodium permanganate, a lithium permanganate, a barium permanganate, a hydrogen permanganate, a sodium chlorate, an aluminum perchlorate, or any combination thereof.

19. The system of claim 16, wherein the at least one rare earth metal salt compound comprises at least one of a rare earth metal oxide compound, a rare earth metal nitrate compound, a rare earth metal oxynitrate compound, or any combination thereof.

20. The system of claim 16, wherein the composition further comprises 0.01% to 5% by weight of at least one metal salt compound based on the total weight of the composition.
